(19) United States
(12) Patent Application Publication
(10) Pub. No.: US 2006/0223214 A1
(43) Pub. Date: Oct. 5, 2006

(54) Optoelectronic component for converting electromagnetic radiation into a intensity-dependent photocurrent

(75) Inventors: Peter Rieve, Windeck-Dattenfeld (DE); Konstantin Seibel, Siegen (DE); Michael Wagner, Bretnig-Hauswalde (DE); Jens Prima, Gehrde (DE); Marcus Walder, Wipperfuerth (DE)

Correspondence Address: STMicroelectronics Inc.;c/o WOLF, GREENFIELD & SACKS, PC, Federal Reserve Plaza, 600 Atlantic Avenue, BOSTON, MA, 02210-2206, US

(73) Assignee: STMicroelectronics N.V., Amsterdam (NL)

(21) Appl. No.: 11/437,499

(22) Filed: May 19, 2006

Related U.S. Application Data
(62) Division of application No. 10/943,448, filed on Sep. 17, 2004.
Application No. 10/943,448 is a continuation of application No. 10/451,440, filed on Feb. 4, 2004, now abandoned.

(30) Foreign Application Priority Data
Dec. 19, 2001 (WO) PCT/EP01/15083
Dec. 20, 2000 (DE) 10063837.6

(51) Int. Cl. H01L 21/00

(52) U.S. Cl. 438/48

(57) ABSTRACT

Optoelectronic component for converting electromagnetic radiation into an intensity-dependent photocurrent comprising a substrate formed in CMOS technology, in particular, with an integrated semiconductor structure (ASIC) and an optically active thin-film structure arranged upstream in the direction of light incidence and comprising in each case at least one layer made of doped and at least one layer made of undoped semiconductor material, which is connected to a microelectronic circuit arranged on the substrate by means of an insulating layer, within which are situated connecting means for contact-connecting the optically active thin-film structure to the semiconductor structure. The invention is based on the object of providing an optoelectronic component, and a method for fabricating it, which, on the one hand, can be fabricated more simply and, on the other hand, has a reduced dark current. This object is achieved according to the invention by virtue of the fact that the optically active thin-film structure has a layer sequence made of a metal and an intrinsically conducting amorphous or microcrystalline semiconductor material, in particular silicon and alloys thereof, which is applied directly to the planarized insulating layer.

### CROSS REFERENCE TO RELATED APPLICATIONS

This application is a divison of application Ser. No. 10/943,448, filed Sep. 17, 2004 which is a continuation of Ser. No. 10/451,440, filed Jun. 20, 2003, entitled “Optoelectronic Component For Converting Electromagnetic Radiation Into An Intensity-Dependent Photocurrent,” which prior applications are incorporated herein by reference.

### BACKGROUND OF THE INVENTION

1. Field of the Invention

The invention relates to an optoelectronic component for converting electromagnetic radiation into an intensity-dependent photocurrent comprising a substrate formed in CMOS technology, in particular, with an integrated semiconductor structure (ASIC) and an optically active thin-film structure arranged upstream in the direction of light incidence and comprising in each case at least one layer made of doped and at least one layer made of undoped semiconductor material, which is connected to a microelectronic circuit arranged on the substrate by means of an insulating layer, within which are situated connecting means for contact-connecting the optically active thin-film structure to the semiconductor structure.

2. Discussion of the Related Art

A method and a component of the type mentioned in the introduction are disclosed in MRS Symposium Proceedings, “Amorphous and Heterogeneous Silicon Thin films 2000”, vol. 609 “Hydrogenated Amorphous Silicon Photodiode Technology for Advanced CMOS Active Pixel Sensors Imagers”, J. A. Theil, M. Cao, G. Kooi, G. W. Ray, W. Greene, J. Lin, A. J. Budrys, U. Yoon, S. Ma and H. Stork.

A component of the type described serves for converting electromagnetic, radiation into an intensity-dependent photocurrent in combination with an optoelectronic sensor in so-called thin film on ASIC (TFA) technology. The electronic circuits arranged on the substrate and serving for the operation of the sensor are, on the one hand, the electronics for driving individual pixels, which are formed on the surface of the substrate either in a matrix-organized manner or in a linear arrangement as individual pixels that are functionally separate from one another and, on the other hand, peripheral electronics for driving the individual pixel electronics and also the superordinate system electronics. The electronics described are usually realized in silicon technology, based on CMOS technology, and conventionally formed by an application specific integrated circuit (ASIC). Situated on this structure, in a manner arranged upstream in the direction of light incidence, are firstly an insulating layer and, on the latter, a multilayer arrangement, i.e. a so-called optically active thin-film system which functions as a photodiode. The connection between the optically active thin-film structure and the electronics realized in the integrated circuit is effected by means of corresponding electrical contacts, so-called vias or tungsten plugs (W plugs). Individual spatially adjacent pixels are in each case arranged in the horizontal plane of the optoelectronic component. Photodiodes assigned to the individual pixels are formed in the optically active thin-film structure, and perform the conversion of electromagnetic radiation

into an intensity-dependent photocurrent. The photocurrent is detected pixel by pixel in accordance with the electromagnetic radiation impinging on the individual pixels and is transferred by means of corresponding contacts, present in each pixel, to the underlying pixel electronics in the ASIC, the control of the exposure and integration operation being undertaken by the peripheral electronics.

In the configuration known from the prior art, the photodiode is formed by a structure which is identical to that of a pin diode, i.e. by a sequence comprising a p-conducting layer, an intrinsically conducting layer and an n-conducting layer. These are amorphous silicon layers in each case. An additional metal layer is formed on that side of the thin-film structure which faces the ASIC, while a transparent conductive layer is present on the side facing the direction of light incidence.

The known optoelectronic component has the disadvantage that it generates a comparatively high dark current. In this case, the term “dark current”. denotes that current of the photodiode which flows and generates a so-called “dark signal” even when the illumination is switched off. Physically, the dark current is instigated by thermal generation of charge carriers in the photodiode. Further causes of the generation of a dark current may also be inhomogeneities. on the surface of the ASIC structure, for example those brought about by metal tracks or holes in a passivation layer. By way of example, at surface edges, during the deposition of the amorphous silicon layers, in particular with the aid of the customary PECVD method (Plasma Enhanced Chemical Vapor Deposition), variations in the layer thicknesses arise which locally result in a higher dark current density and may determine the overall magnitude of the dark current. These additional dark currents attributed to the surface topography of an ASIC—of the photodiodes situated thereon may exceed the thermal generation currents by many orders of magnitude and thus generate a significant dark signal. Consequently, the image quality of the sensor is greatly reduced at low illumination intensities, resulting in a lower sensitivity.

A further disadvantage of the arrangement described is that the method for fabricating the component is comparatively complicated owing to the multiplicity of photolithography processes. In particular, the photolithographic patterning step for the pixel-by-pixel separation of the doped silicon layers situated on the photodiode rear contacts is critical because the vacuum process for carrying out the photolithography step has to be interrupted, which adversely affects the dark current of the photodiodes and the yield.

### SUMMARY OF THE INVENTION

Therefore, the invention is based on the object of providing an optoelectronic component, and a method for fabricating it, which, on the one hand, can be fabricated more simply and, on the other hand, has a reduced dark current.

In the case of a component of the type mentioned in the introduction, this object is achieved according to the invention by virtue of the fact that the optically active thin-film structure has a layer sequence made of a metal and an intrinsically conducting amorphous or microcrystalline semiconductor, in particular silicon and alloys thereof, which is applied directly to the insulating layer. In the case of a method of the type mentioned in the introduction, this object is achieved by virtue. of the fact that an optically active thin-film structure, which has a layer sequence made of a metal and an intrinsically conducting amorphous or microcrystalline semiconductor material, in particular silicon or alloys thereof, is applied directly to the planarized insulating layer.

The invention is distinguished by the fact that a metal-semiconductor junction in the manner of a Schottky diode is used instead of the pin diode known from the prior art within the optically active thin-film structure. In the fabrication of the component, an additional photolithographic patterning step is avoided by virtue of the simplification of the structure. Furthermore, the structure described has the advantage that it is. situated on a planarized ASIC surface, i.e. on a surface topography that is planar in comparison with the thickness of the photodiode, so that a significantly lower dark current is produced as a result of this.

Further preferred embodiments of the invention emerge from the subclaims.

### BRIEF DESCRIPTION OF THE DRAWINGS

The invention is explained in more detail below with reference to a drawing, in which:

FIG. 1 shows the structure of an optoelectronic component according to the prior art;

FIG. 2 shows the structure of an optoelectronic component in cross section in accordance with an exemplary embodiment of the present invention.

### DETAILED DESCRIPTION

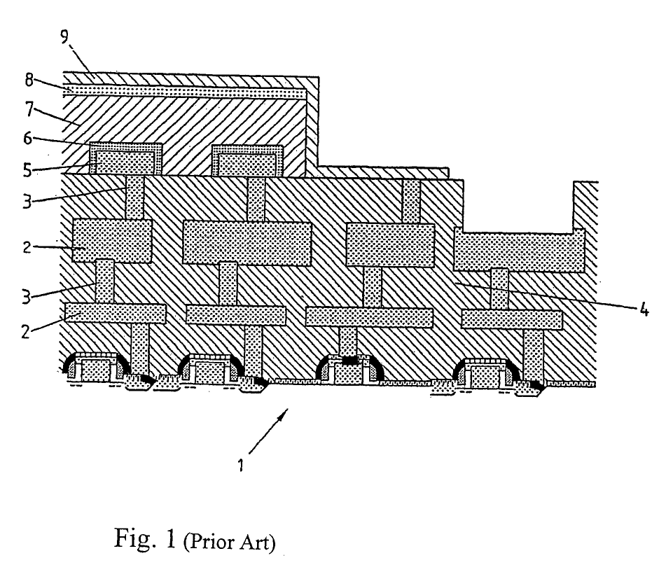

The optoelectronic component in accordance with the prior art as illustrated in FIG. 1 comprises a substrate 1, i.e. a silicon substrate, on whose surface corresponding integrated circuits are formed. The technology used in this case is realized in CMOS technology, and the circuit thus formed is referred to as an application specific integrated circuit ASIC. An insulating layer 4 applied on the surface of the ASIC, accommodated within which insulating layer are metallizations 2 which extend essentially horizontally and which are electrically connected to one another by means of vias 3, serves for contact-connecting the ASIC to an optical thin-film structure, comprising the layers 5, 6, 7, 8, 9, that is yet to be described. Consequently, a direct electrical contact is produced between the desired positions on the surface of the integrated circuit and a metal layer 5 representing the bottommost layer of the optical structure, facing the ASIC.

Each of the metal layer contacts 5, which serves as base connection for the individual pixel contacts, is covered with an amorphous silicon layer 6, which overlaps the metal layer 5 and is formed as an n-type a-Si:H layer. Situated above that is an intrinsically conducting amorphous silicon layer 7, on which, in turn, a p-type-doped, amorphous silicon layer 8 is situated. The entire structure thus formed is covered with a layer made of a conductive transparent oxide 9, which represents that layer of the overall structure which is arranged upstream in the direction of light incidence.

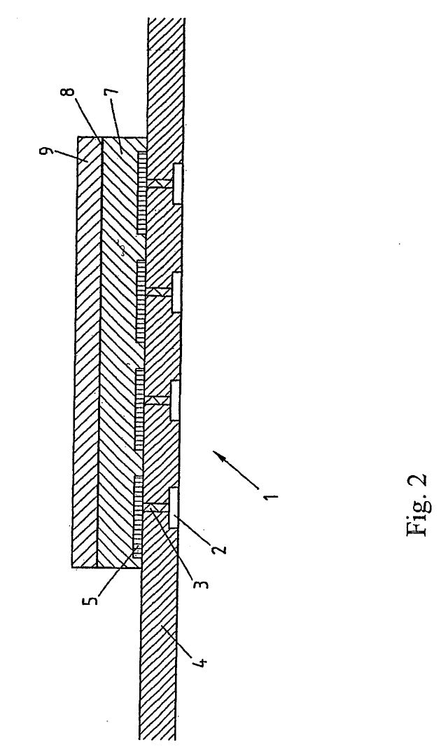

By contrast, FIG. 2 shows the construction of an optoelectronic component in accordance with an exemplary embodiment of the present invention:

An insulating layer 4, a so-called intermetallic dielectric. layer, is applied to the substrate 1 with the ASIC, which is formed in a manner corresponding to that in the prior art, which layer has been planarized by means of chemical mechanical polishing, so that the metallic contact connections, that is to say the horizontal connecting means 2 and the vias 3, are embedded in the intermetallic dielectric layer in such a way that no appreciable surface roughnesses arise. The connections between the individual metal layers 2 is effected by connecting vias 3 made of tungsten. The latter are also referred to as W plugs. According to a preferred exemplary embodiment of the invention, a titanium nitride barrier layer is additionally introduced between the insulating layer 4 and the metal layer 5, described below. Situated above said barrier layer is a metal layer 5 made of chromium, which has a thickness of 100 nm or less and is applied for example by the method of sputtering. This metal layer is patterned in such a manner as to produce back electrodes for the individual pixels. Situated above the metal layer 5 is an intrinsically conducting layer 7 of amorphous or microcrystalline silicon or alloys

thereof, which has a thickness of typically approximately 0.5 μm to 2 μm and is preferably applied .by the. PECVD method. Finally, situated above the intrinsically conducting layer 7 is a p-conducting layer made. of amorphous or microcrystalline silicon 8 or alloys thereof, which has a thickness of typically approximately 5 nm to 20 nm. A front contact in the form of a conductive transparent oxide layer is situated on the p-conducting layer 8. The material used for this is preferably aluminum-doped zinc oxide, aluminum-oxide-doped zinc oxide or, alternatively, indium tin oxide.

The layer sequence metal—chromium/intrinsically conducting amorphous silicon produces the structure of a Schottky diode in the form of a metal-semiconductor junction on a planarized ASIC surface.

This results in an extreme reduction of the dark current in comparison with the prior art.

Furthermore, the fabrication of the component according to the invention is also very much simpler since a photolithographic step for fabricating an additional n-doped silicon layer is obviated.

Such alterations, modifications, and improvements are intended to be part of this disclosure, and are intended to be within the spirit and the scope of the present invention. Accordingly, the foregoing description is by way of example only and is not intended to be limiting. The present invention is limited only as defined in the following claims and the equivalents thereto.

What is claimed is:

1. A method for fabricating an optoelectronic component for converting electromagnetic radiation into an intensity-dependent photocurrent comprising a substrate formed in CMOS technology, with an integrated semiconductor structure and an optically active thin-film structure arranged upstream in the direction of light incidence and comprising at least one layer made of doped and at least one layer made of undoped semiconductor material, which is connected to a microelectronic circuit arranged on the substrate by means of an insulating layer, within which are situated connecting means for contact-connecting the optically active thin-film structure to the semiconductor structure, wherein the optically active thin-film structure is applied to the planarized insulating layer, wherein the thin-film structure has a layer sequence made of a plurality of metal electrodes and an intrinsically conducting layer that contacts the plurality of metal electrodes, made of amorphous or microcrystalline semiconductor material, such as silicon or alloys thereof, and further comprising an extrinsically conducting layer that contacts the intrinsically conducting layer and a conductive transparent layer disposed on the layer sequence.

2. The method for fabricating an optoelectronic component as claimed in claim 1, wherein the metal/intrinsic semiconductor layer sequence is applied on a planarized integrated semiconductor structure.

3. The method for fabricating an optoelectronic component as claimed in claim 2, wherein the integrated semiconductor structure is planarized by means of chemical mechanical polishing.

4. The method for fabricating an optoelectronic component as claimed in claim 1, wherein the topmost metal layer of the integrated semiconductor structure is completely or partially removed.

5. A method of forming an optoelectronic component, the method comprising:
forming a plurality of metal regions;
forming a region of intrinsic semiconductor that contacts the plurality of metal regions;
forming a region of extrinsic semiconductor that contacts the region of intrinsic semiconductor; and
forming a region of conductive transparent material that is coupled to the region of extrinsic semiconductor.

6. The method of claim 5, wherein the plurality of metal regions are formed on a planarized insulating layer.

7. The method of claim 5, further comprising forming a plurality of Schottky diodes.

8. The method of claim 5, wherein the region of intrinsic semiconductor is formed over an entire region that includes the plurality of metal regions.

9. The method of claim 5, wherein the plurality of metal regions are formed at least partially by a sputtering method.

10. The method of claim 6, further comprising forming conductive vias that extend through the planarized insulating layer.

11. The method of claim 5, wherein the region of extrinsic semiconductor is formed over the region of intrinsic semiconductor and covers an entire region that includes the plurality of metal regions.

12. The method of claim 5, further comprising forming the plurality of metal regions by patterning a metal layer in such a manner as to produce electrodes for individual pixels, wherein the plurality of metal regions are formed prior to forming the region of intrinsic semiconductor.
